(19) United States
(12) Patent Application Publication
(10) Pub. No.: US 2023/0343896 A1
(43) Pub. Date: Oct. 26, 2023

(54) SEMICONDUCTOR DEVICE

(71) Applicant: EPISTAR CORPORATION, Hsinchu (TW)

(72) Inventors: Wei-Shan YEOH, Hsinchu (TW); Tzu-Yun FENG, Hsinchu (TW)

(21) Appl. No.: 18/138,665

(22) Filed: Apr. 24, 2023

(30) Foreign Application Priority Data
Apr. 26, 2022 (TW) 111115765

(51) Int. Cl. H01L 33/38; H01L 33/60

(52) U.S. Cl. CPC H01L 33/38; H01L 33/60

(57) ABSTRACT

A semiconductor device is provided, which includes a semiconductor epitaxial structure, a metal contact structure, and a metal oxide layer. The semiconductor epitaxial structure includes an active structure and a semiconductor contact layer located on the active structure along a vertical direction. The metal contact structure directly contacts the semiconductor contact layer. The metal oxide layer is overlapped with the metal contact structure in a horizontal direction. The metal oxide layer and the metal contact structure are separated in the horizontal direction.

### CROSS REFERENCE TO RELATED APPLICATIONS

This application claims the right of priority based on TW application Serial No. 111115765, filed on Apr. 26, 2022, which is incorporated by reference herein in their entirety.

### FIELD OF DISCLOSURE

The present disclosure relates to a semiconductor device, in particular, to a semiconductor device having a metal contact structure.

### BACKGROUND OF THE DISCLOSURE

Semiconductor devices can be applied to a wide range of applications. Research and development of related materials have been continuously carried out. For example, a group III-V semiconductor material containing a group III element and a group V element may be applied to various optoelectronic semiconductor devices, such as light-emitting diodes (LEDs), laser diodes (LDs), photoelectric detectors, solar cells or power devices (such as switches or rectifiers). These optoelectronic semiconductor devices can be applied in various fields, such as illumination, medical care, display, communication, sensing, or power supply system. For example, in semiconductor light-emitting devices, LEDs have low energy consumption, rapid response, small volume and long operating lifetime, thus are widely used.

### SUMMARY OF THE DISCLOSURE

The present disclosure provides a semiconductor device. The semiconductor device includes a semiconductor epitaxial structure, a metal contact structure, and a metal oxide layer. The semiconductor epitaxial structure includes an active structure and a semiconductor contact layer located on the active structure along a vertical direction. The metal contact structure directly contacts the semiconductor contact layer. The metal oxide layer is overlapped with the metal contact structure in a horizontal direction. The metal oxide layer and the metal contact structure are separated in the horizontal direction.

### BRIEF DESCRIPTION OF THE DRAWINGS

FIG. 1 shows a top perspective schematic view of a semiconductor device according to an embodiment of the present disclosure.

FIG. 2 shows a schematic cross-sectional view of the semiconductor device in FIG. 1 along the section line A-A′.

FIG. 3 shows a partially enlarged schematic view of a region R of the semiconductor device in FIG. 2.

FIG. 4 shows a schematic cross-sectional view of a semiconductor device according to an embodiment of the present disclosure.

FIG. 5 shows a schematic cross-sectional view of a semiconductor device according to an embodiment of the present disclosure.

FIG. 6 shows a schematic cross-sectional view of a semiconductor device according to an embodiment of the present disclosure.

FIG. 7 shows a schematic cross-sectional view of a package structure of a semiconductor device according to an embodiment of the present disclosure.

### DETAILED DESCRIPTION OF THE DISCLOSURE

The following embodiments will be described with accompany drawings to disclose the concept of the present disclosure. In the drawings or description, same or similar portions are indicated with same or similar numerals. Furthermore, a shape or a size of a component in the drawings may be enlarged or reduced. Particularly, it should be noted that a component which is not shown or described in drawings or description may be in a form that is known by a person skilled in the art.

In addition, if not otherwise specified, a description similar to “a first layer/structure is on or under a second layer/structure” may include an embodiment in which the first layer/structure directly (or physically) contacts the second layer/structure, and may also include an embodiment in which another structure is provided between the first layer/structure and the second layer/structure, such that the first layer/structure and the second layer/structure do not directly contact each other. Furthermore, it should be realized that a positional relationship of a layer/structure may be altered when being observed in different orientations.

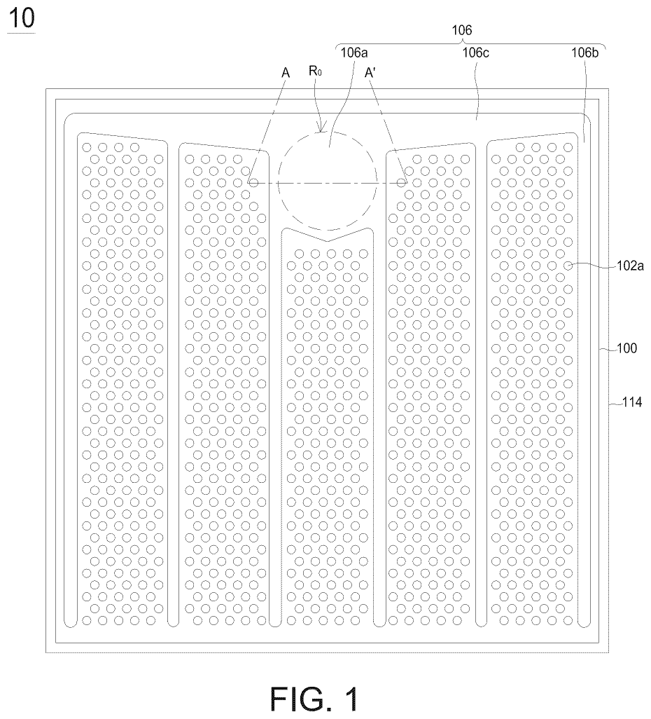

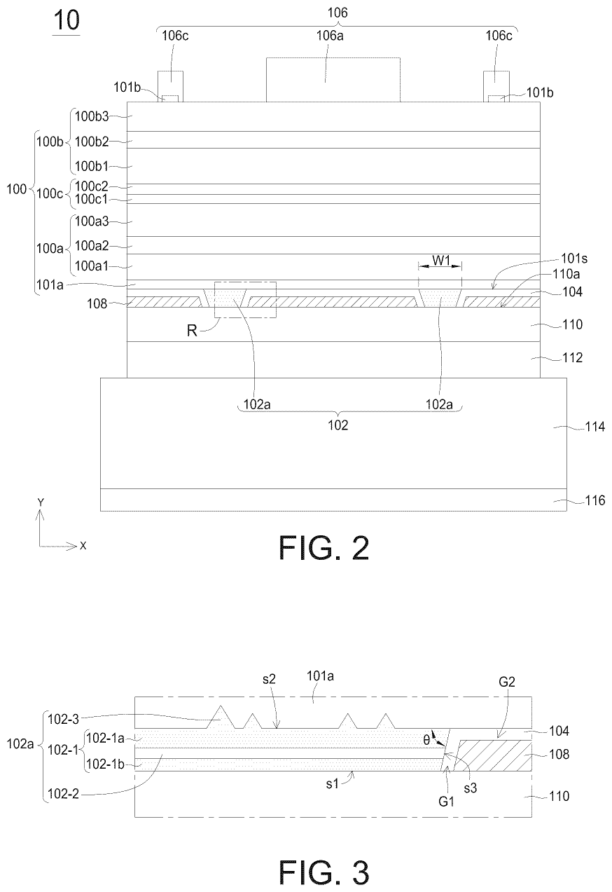

Referring to FIG. 1 to FIG. 3 for the following embodiments, in which FIG. 1 shows a top perspective schematic view of a semiconductor device according to an embodiment of the present disclosure; FIG. 2 shows a schematic cross-sectional view of the semiconductor device in FIG. 1 along the section line A-A′; FIG. 3 shows a partially enlarged schematic view of a region R of the semiconductor device in FIG. 2. For clarity, the coordinate axes marked in FIG. 2 can be referred to in the following embodiments. A “width” of each component refers to a value measured along a horizontal direction X; a “thickness” of each component refers to a value measured along a vertical direction Y; a “stacking direction” refers to the vertical direction Y or a direction opposite to the vertical direction Y, and the vertical direction Y and the horizontal direction X are perpendicular to each other.

As shown in FIG. 2, the semiconductor device 10 of this embodiment includes a semiconductor epitaxial structure 100 and a metal contact structure 102. In addition, the semiconductor device 10 may optionally include an insulating layer 104, a first electrode 106, a metal oxide layer 108, a reflective layer 110, a base 114 and a second electrode 116. The bonding layer 112 is located between the semiconductor epitaxial structure 100 and the base 114. The reflective layer 110 is located between the bonding layer 112 and the semiconductor epitaxial structure 100. The metal contact structure 102, the insulating layer 104 and the metal oxide layer 108 are located between the semiconductor epitaxial structure 100 and the reflective layer 110. The first electrode 106 and the second electrode 116 are respectively located on two sides of the semiconductor device 10 for electrically connecting an external power source. As shown in FIG. 2, the first electrode 106 is located on the semiconductor epitaxial structure 100, and the second electrode 116 is located under the base 114. In the embodiment, the semiconductor epitaxial structure 100 can be electrically connected to the reflective layer 110, the bonding layer 112 and the base 114 through the metal contact structure 102. In an embodiment, the semiconductor epitaxial structure 100 is formed on an epitaxial growth substrate through an epitaxial growth process, and then the semiconductor epitaxial structure 100 is bonded to the base 114 through the bonding layer 112, and after the bonding process is completed, the epitaxial growth substrate is removed, so that the semiconductor device 10 can be formed.

The semiconductor epitaxial structure 100 may include a first semiconductor contact layer 101a. In the embodiment, the first semiconductor contact layer 101a is the semiconductor layer closest to the base 114 in the semiconductor epitaxial structure 100. As shown in FIG. 2, in the vertical direction Y, the metal contact structure 102 is located between the first semiconductor contact layer 101a and the reflective layer 110. The metal oxide layer 108 is located between the first semiconductor contact layer 101a and the reflective layer 110. In the horizontal direction X, the metal oxide layer 108 is overlapped with the metal contact structure 102, that is, the metal oxide layer 108 and the metal contact structure 102 are arranged side by side horizontally on an upper surface 110a of the reflective layer 110. As shown in FIG. 3, the metal oxide layer 108 and the metal contact structure 102, and the metal oxide layer 108 and the first semiconductor contact layer 101a may be separated by gaps. In detail, in the horizontal direction X, the metal oxide layer 108 is separated from the metal contact structure 102 by a gap G1, so that the metal oxide layer 108 does not directly contact the metal contact structure 102; in the vertical direction Y, the metal oxide layer 108 is separated from the first semiconductor contact layer 101a by a gap G2, so that the metal oxide layer 108 does not directly contact the first semiconductor contact layer 101a. As shown in FIG. 2, the insulating layer 104 can fill the gap G1 and the gap G2 to separate the metal oxide layer 108 from the metal contact structure 102, and to separate the metal oxide layer 108 from the first semiconductor contact layer 101a. In this embodiment, both the insulating layer 104 and the metal contact structure 102 are in direct contact with a lower surface 101s of the first semiconductor contact layer 101a. In detail, a portion of the lower surface 101s of the first semiconductor contact layer 101a not in direct contact with the metal contact structure 102 directly contacts the insulating layer 104. According to an embodiment, the first semiconductor contact layer 101a may have a higher dopant concentration (such as a concentration larger than or equal to 1×10¹⁸/cm³ or larger than or equal to 1×10¹⁹/cm³) so as to form a low-resistance interface (such as an ohmic contact) with the metal contact structure 102. Since a resistance between the insulating layer 104 and the first semiconductor contact layer 101a is higher than a resistance value between the metal contact structure 102 and the first semiconductor contact layer 101a, a current path can be formed mainly at a portion of the metal contact structure 102 which is in direct contact with the first semiconductor contact layer 101a. By changing the relative positions of the insulating layer 104 and the metal contact structure 102, a current spreading effect of the semiconductor device 10 can be improved, thereby improving the electrical performance of the semiconductor device 10.

In this embodiment, the metal contact structure 102 includes a plurality of metal pillars 102a separated from each other. For convenience, one of the metal pillars 102a is taken as an example below to show the relative relationship of each component. As shown in FIG. 2, along the vertical direction Y, the insulating layer 104 is located between the first semiconductor contact layer 101a and the metal oxide layer 108, and is in direct contact with a portion of the metal pillar 102a. Specifically, as shown in the partially enlarged schematic view of the region R in FIG. 3, the metal pillar 102a may have a first surface s1, a second surface s2, and a side surface s3, and the first surface s1 is farther from the first semiconductor contact layer 101a than the second surface s2 is, the side surface s3 connects the first surface s1 and the second surface s2. In a cross-section of the semiconductor device 10, the second surface s2 and the side surface s3 can form an acute angle θ, that is, the side surface s3 is an inclined plane, so that the insulating layer 104 can cover on the side surface s3 of the metal pillar 102a more easily. In an embodiment, the whole side surface s3 is directly covered by the insulating layer 104, thereby separating the metal pillar 102a and the metal oxide layer 108 in the horizontal direction X. In an embodiment, the second surface s2 of the metal pillar 102a is directly connected to the first semiconductor contact layer 101a, and the first surface s1 of the metal pillar 102a is directly connected to the reflective layer 110.

As shown in FIG. 3, the metal pillar 102a may include one or a plurality of main contact layers 102-1. The main contact layer 102-1 may be in direct contact with the first semiconductor contact layer 101a and the reflective layer 110, so as to be in direct contact with the first semiconductor contact layer 101a and the reflective layer 110 and form an electrical contact. The material of the main contact layer 102-1 may include metal, such as gold (Au), silver (Ag), an alloy containing gold, such as beryllium gold (BeAu) or zinc gold (ZnAu), or an alloy containing silver. According to some embodiments, when the material of the main contact layer 102-1 does not contain alloy such as beryllium gold (BeAu) or zinc gold (ZnAu) at all (for example, the material of the main contact layer 102-1 is gold (Au) and there is no beryllium (Be) or zinc (Zn) in the main contact layer 102-1), the electrical contact (such as an ohmic junction) between the metal contact structure 102 and the first semiconductor contact layer 101a can be formed at a relatively low process temperature, so as to prevent the light emitted by the semiconductor epitaxial structure 100 from being absorbed by an alloy formed at the interface between the metal contact structure 102 and the first semiconductor contact layer 101a under a high temperature during a manufacturing process. In an embodiment, the metal pillar 102a may optionally include a barrier layer 102-2. As shown in FIG. 3, in the embodiment, the metal pillar 102a includes a first main contact layer 102-1a and a second main contact layer 102-1b. The first main contact layer 102-1a is closer to the first semiconductor contact layer 101a than the second main contact layer 102-1b is. The first main contact layer 102-1a directly contacts the first semiconductor contact layer 101a. The second main contact layer 102-1b directly contacts the reflective layer 110. The barrier layer 102-2 is formed between the first main contact layer 102-1a and the second main contact layer 102-1b and is in direct contact with the insulating layer 104. The barrier layer 102-2 connects the first main contact layer 102-1a and the second main contact layer 102-1b. The barrier layer 102-2 is closer to the semiconductor epitaxial structure 100 than the second main contact layer 102-1b is. The barrier layer 102-2 may prevent interdiffusion of material between the reflective layer 110 and the first semiconductor contact layer 101a that may affect reflectivity. For example, the barrier layer 102-2 may prevent the material of the reflective layer 110 from diffusing into the first semiconductor contact layer 101a, so as to prevent excessive material of the reflective layer 110 from forming an alloy with the material of the metal pillar 102a and/or the first semiconductor contact layer 101a and affecting the reflectivity. According to an embodiment, the material of the barrier layer 102-2 may include metal or alloy, such as tantalum (Ta), titanium (Ti), platinum (Pt) or titanium tungsten (TiW).

In an embodiment, the metal pillar 102a may optionally include one or a plurality of protrusions 102-3. As shown in FIG. 3, the protrusion 102-3 may protrude from the second surface s2 toward the first electrode 106 along the vertical direction Y and be embedded in the first semiconductor contact layer 101a. Any two of the plurality of protrusions 102-3 can be separated or connected to each other. In this embodiment, the cross-sectional shape of the protrusions 102-3 is, for example, roughly triangular, trapezoidal, semicircular or in another shape having an arc. The plurality of protrusions 102-3 may have the same or different dimensions. According to some embodiments, the protrusion 102-3 can increase the contact area between the first semiconductor contact layer 101a and the metal pillar 102a, thereby improving the adhesion between the first semiconductor contact layer 101a and the metal pillar 102a, and can reduce the resistance between the first semiconductor contact layer 101a and the metal pillar 102a. The protrusions 102-3 may contain the same material as the main contact layer 102-1. According to an embodiment, the protrusion 102-3 may include the material of the main contact layer 102-1, the material of the first semiconductor contact layer 101a and/or the material of the reflective layer 110, or an alloy containing these materials. For example, when the first semiconductor contact layer 101a includes a binary, ternary or quaternary III-V compound semiconductor material including aluminum (Al), gallium (Ga), indium (In), nitrogen (N), phosphorus (P) or arsenic (As), such as gallium phosphide (GaP), gallium arsenide (GaAs), or indium gallium arsenide (InGaAs). the material of the main contact layer 102-1 includes gold (Au), and the material of the reflective layer 110 includes silver (Ag), the protrusions 102-3 may contain two or more elements of gallium (Ga), gold (Au) and silver (Ag), or an alloy formed by two or more of these elements (such as GaAuAg, AuAg, or GaAu).

Referring to FIG. 2, in a cross-section of the semiconductor device 10, the shape of the metal pillar 102a is roughly an inverted trapezoid. The inverted trapezoid includes a long side and a short side parallel to each other, and two hypotenuses connecting the long side and the short side. The short side is closer to the base 114 than the long side is. In an embodiment, a thickness of the metal oxide layer 108 is less than a thickness of the metal pillar 102a. In the vertical direction Y, the sum of the thicknesses of the metal oxide layer 108 and the insulating layer 104 can be the same with the thickness of the metal pillar 102a, or there is a difference of less than 1 μm between the sum and the thickness of the metal pillar 102a. In an embodiment, the thickness of the metal pillar 102a may range from 1000 Å to 1 μm. According to some embodiments, when the thickness of the metal pillar 102a is 1000 Å or more, the semiconductor device 10 may have a better luminous power. According to an embodiment, the adhesion between the metal oxide layer 108 and the insulating layer 104 may be greater than the adhesion between the insulating layer 104 and the reflective layer 110, or the adhesion between the metal oxide layer 108 and the reflective layer 110 may be greater than that between the insulating layer 104 and the reflective layer 110, thereby the metal oxide layer 108 may enhance the adhesion between the insulating layer 104 and the reflective layer 110, and further improve the structural strength of the semiconductor device 10. In an embodiment, the reflective layer 110 directly contacts the metal oxide layer 108, the insulating layer 104 and the metal contact structure 102. In an embodiment, the cross-sectional shape of the metal oxide layer 108 may include a polygon, such as a trapezoid or a rectangle.

As shown in FIG. 1, the first electrode 106 is located on the semiconductor epitaxial structure 100. The first electrode 106 may include an electrode pad 106a, a plurality of extension electrodes 106b, and a connecting portion 106c. The electrode pad 106a provides an electrical junction for connection to an external power source or other components. The plurality of extension electrodes 106b are separated from each other and connected to the electrode pads 106a through the connecting portion 106c. For example, the extension electrodes 106b are finger-shaped, arranged parallel to each other and extended to the periphery of the semiconductor device 10. As shown in FIG. 1 and FIG. 3, in an embodiment, the first electrode 106 and the metal contact structure 102 do not have an overlapping region in the vertical direction Y, thereby preventing current paths from being excessively concentrated at the position directly under the first electrode 106, and when the material of the first electrode 106 is more likely to absorb the light emitted by the semiconductor epitaxial structure 100, this arrangement can reduce the light absorption by the first electrode 106. In an embodiment, a protective layer (not shown) may be covered on the first electrode 106 and the semiconductor epitaxial structure 100, so as to isolate external pollutants and the like, and to further protect the semiconductor device 10. As shown in FIG. 1, when viewed from above, there is a region R0 on a surface of the first electrode 106, and the protective layer can cover on the portion outside the region R0. With this configuration, a part of the first electrode 106 within the region R0 is not covered by the protective layer and can be exposed from the protective layer and be electrically connected to an external power source. The top-view shape of the region R0 can be circular, elliptical or polygonal.

As shown in FIG. 1, the metal pillars 102a of the metal contact structure 102 are evenly distributed between two adjacent extension electrodes 106b. With this design, when operating the semiconductor device 10, the current can be evenly distributed into the semiconductor epitaxial structure 100, for example, the semiconductor device 10 can have better luminous uniformity. As shown in FIG. 1, the plurality of metal pillars 102a of the metal contact structure 102 can be arranged in a two-dimensional dot array. According to some embodiments, the top-view shape of each metal pillar 102a is, for example, polygonal (such as rectangular, pentagonal, or hexagonal), circular or elliptical. It should be noted that since the metal contact structure 102 is located inside the semiconductor device 10, the metal contact structure 102 cannot be directly observed from the appearance of the semiconductor device 10. Therefore, what is shown in FIG. 1 is a top perspective schematic view of the semiconductor device 10, and all the components are drawn in solid lines. In an embodiment, the plurality of metal pillars 102a can be distributed between two adjacent extension electrodes 106c (as shown in FIG. 1), and optionally, can also be distributed between the extension electrodes 106c and outer boundaries of the semiconductor epitaxial structure 100 to further enhance the current spreading effect.

As shown in FIG. 2, the semiconductor device 10 further includes a second semiconductor contact layer 101b located between the first electrode 106 and the semiconductor epitaxial structure 100. According to an embodiment, the second semiconductor contact layer 101b may have a higher dopant concentration (such as a concentration greater than or equal to 1×10¹⁸/cm³ or greater than or equal to 1×10¹⁹/cm³) to form an electrical contact (such as an ohmic contact) with the first electrode 106. The second semiconductor contact layer 101b may be a patterned semiconductor contact layer. In an embodiment, the second semiconductor contact layer 101b may overlap with the plurality of extension electrodes 106b and the connecting portion 106c of the first electrode 106 in the vertical direction, but not overlap with the electrode pad 106a. As shown in FIG. 2, an upper surface and a side surface of the second semiconductor contact layer 101b can be in direct contact with the connecting portion 106c (or a plurality of extension electrodes 106b), so as to increase the contact area.

The semiconductor epitaxial structure 100 includes a first light-emitting stack 100a located between the first electrode 106 and the first semiconductor contact layer 101a. The first light-emitting stack 100a may include a first semiconductor structure 100a1, a second semiconductor structure 100a3, and a first active structure 100a2. The second semiconductor structure 100a3 is located on the first semiconductor structure 100a1, and the first active structure 100a2 is located between the first semiconductor structure 100a1 and the second semiconductor structure 100a3. The first light-emitting stack 100a can emit light having a first peak wavelength Wp1 during operation. The refractive index of the insulating layer 104 can be smaller than that of the first semiconductor contact layer 101a, and a total reflection interface can be formed between the insulating layer 104 and the first semiconductor contact layer 101a, so as to improve light extraction efficiency. In an embodiment, the refractive index of the insulating layer 104 can be smaller than that of the metal oxide layer 108, and the refractive index of metal oxide layer 108 can be smaller than that of the first semiconductor contact layer 101a. According to some embodiments, a ratio of the area of the metal contact structure 102 to the area of the first active structure 100a2 can be set to be less than 15%, so as to reduce the possible light-shielding or light-absorbing effect of the metal contact structure 102, and can be set to be more than 1% to provide an electrical contact. According to some embodiments, the ratio of the area of the metal contact structure 102 to the area of the first active structure 100a2 is, for example, in the range of 2% to 10%. As shown in FIG. 2, each metal pillar 102a in the metal contact structure 102 may have a width W1. The width W1 may be within a range greater than 0 μm and less than 10 μm, for example, between 1 μm and 6 μm. According to some embodiments, when the width W1 is less than 10 μm, the optical performance of the semiconductor device 10 can be further improved. In an embodiment, in the horizontal direction X, the shortest distance between each metal pillar 102a and the nearest extension electrode 106c is greater than the width W1 of each metal pillar 102a, for example, greater than twice of the width W1, so as to reduce the light-shading or light-absorbing effect caused by the extension electrode 106c. The aforementioned shortest distance is, for example, in the range of 5 μm to 30 μm. According to some embodiments, when the above-mentioned shortest distance is greater than 5 μm, the light-shielding or light-absorbing effect of the extension electrode 106c can be effectively avoided, and the optical performance of the semiconductor device 10 can be further improved. According to some embodiments, when the above-mentioned shortest distance is less than 30 μm, a large increase of the forward voltage of the semiconductor device 10 results from the excessive distance between the extension electrode 106c and the metal pillar 102a in the horizontal direction X can be avoided. In an embodiment, the metal contact structure 102 has a reflectivity greater than 80% for the light emitted by the first light-emitting stack 100a, so as to further reduce the light-shielding or light-absorbing effect of the metal contact structure 102. The metal oxide layer 108 can be transparent to the light emitted by the first light-emitting stack 100a, for example, has a transmittance of 70% or higher.

As shown in FIG. 2, the semiconductor epitaxial structure 100 may optionally further include a second light-emitting stack 100b stacked on the first light-emitting stack 100a along the vertical direction Y. The second light-emitting stack 100b includes a third semiconductor structure 100b1, a fourth semiconductor structure 100b3 and a second active structure 100b2. The fourth semiconductor structure 100b3 is located on the third semiconductor structure 100b1, and the second active structure 100b2 is located between the third semiconductor structure 100b1 and the fourth semiconductor structure 100b3. When operating the semiconductor device 10, the first active structure 100a1 can emit a light with a first peak wavelength Wp1 and the second active structure 100b2 can emit a light with a second peak wavelength Wp2. The first peak wavelength Wp1 and the second peak wavelength Wp2 may be the same or different. In an embodiment, the second peak wavelength Wp2 is less than or equal to the first peak wavelength Wp1.

According to an embodiment, the semiconductor device 10 is a light-emitting device (such as a light-emitting diode), and when the semiconductor device 10 is operated, the light emitted by the first active structure 100a1 and the second active structure 100b2 may respectively include visible light or invisible light. The first peak wavelength Wp1 and the second peak wavelength Wp2 may subject to the material composition of the first active structure 100a1 and the second active structure 100b2. For example, when the material of the first active structure 100a1/the second active structure 100b2 includes InGaN series, for example, it can emit blue light or deep blue light with a peak wavelength of 400 nm to 490 nm, or green light with a peak wavelength of 490 nm to 550 nm; when the material of the first active structure 100a1/the second active structure 100b2 includes AlGaN series, for example, it can emit ultraviolet light with a peak wavelength of 250 nm to 400 nm; when the material of the first active structure 100a1/the second active structure 100b2 includes InGaAs series, InGaAsP series, AlGaAs series or AlGaInAs series, for example, it can emit infrared light with a peak wavelength of 700 to 1700 nm; when the material of the first active structure 100a1/the second active structure 100b2 includes InGaP series or AlGaInP series, for example, it can emit red light with a peak wavelength of 610 nm to 700 nm, or yellow light with a peak wavelength of 530 nm to 600 nm.

As shown in FIG. 2, the semiconductor epitaxial structure 100 may optionally further include a tunneling structure 100c stacked between the first light-emitting stack 100a and the second light-emitting stack 100b along the vertical direction Y for electrically connecting the first light-emitting stack 100a and the second light-emitting stack 100b. The tunneling structure 100c further includes a first tunneling layer 100c1 and a second tunneling layer 100c2. As shown in FIG. 2, the first tunneling layer 100c1 is located between the second tunneling layer 100c2 and the first light-emitting stack 100a. The first tunneling layer 100c1 and the second tunneling layer 100c2 may have different conductivity types. In an embodiment, the first tunneling layer 100c1 and the second tunneling layer 100c2 have a doping concentration higher than 1×10¹⁸ cm⁻³. For example, the doping concentration is between 5×10¹⁸ cm⁻³ and 1×22¹⁸ cm⁻³ (both inclusive). In this embodiment, the first light-emitting stack 100a and the second light-emitting stack 100b are connected in series through the tunneling structure 100c.

According to an embodiment, the semiconductor epitaxial structure 100 may have the first light-emitting stack 100a and do not have the second light-emitting stack 100b and the tunneling structure 100c. In this case, the second semiconductor contact layer 101b may be located on the second semiconductor structure 100a3 and be in direct contact with the second semiconductor structure 100a3.

The first semiconductor structure 100a1 and the second semiconductor structure 100a3 have different conductivity types, for example, the first semiconductor structure 100a1 is a p-type semiconductor, and the second semiconductor structure 100a3 is an n-type semiconductor; or the first semiconductor structure 100a1 is an n-type semiconductor type semiconductor, and the second semiconductor structure 100a3 is a p-type semiconductor. The first tunneling layer 100c1 and the second tunneling layer 100c2 may have different conductivity types, for example, the first tunneling layer 100c1 is an n-type semiconductor, and the second tunneling layer 100c2 is a p-type semiconductor; or the first tunneling layer 100c1 is a p-type semiconductor, and the second tunneling layer 100c2 is an n-type semiconductor. The first tunneling layer 100c1 and the second semiconductor structure 100a3 may have the same conductivity type. The third semiconductor structure 100b1 and the fourth semiconductor structure 100b3 may have different conductivity types, for example, the third semiconductor structure 100b1 is a p-type semiconductor and the fourth semiconductor structure 100b3 is an n-type semiconductor; or the third semiconductor structure 100b1 is an n-type semiconductor and the fourth semiconductor structure 100b3 is a p-type semiconductor. The third semiconductor structure 100b1 and the second tunneling layer 100c2 may have the same conductivity type. The n-type semiconductor is, for example, a semiconductor doped with tellurium (Te) or silicon (Si), and the p-type semiconductor is, for example, a semiconductor doped with carbon (C), zinc (Zn) or magnesium (Mg).

In an embodiment, the first semiconductor structure 100a1, the second semiconductor structure 100a3, the third semiconductor structure 100b1 and the fourth semiconductor structure 100b3 may respectively include a single layer or a multi-layer. For example, the first active structure 100a2 and the second active structure 100b1 respectively include a multiple quantum well structure. The first semiconductor structure 100a1, the first active structure 100a2, the second semiconductor structure 100a3 and the first semiconductor contact layer 101a may each include the same series of binary, ternary or quaternary III-V semiconductor materials. The third semiconductor structure 100b1, the fourth semiconductor structure 100b3, the second active structure 100b1 and the second semiconductor contact layer 101b may each include the same series of binary, ternary or quaternary III-V semiconductor materials. The binary, ternary or quaternary III-V semiconductor materials include, for example, AlInGaAs series, AlGaInP series, AlInGaN series or InGaAsP series, in which the AlInGaAs series can be indicated as (Alₓ₁In₍₁₋ₓ₁₎)₁₋ₓ₂Gaₓ₂As; the AlInGaP series can be indicated as (Al_{y1}In_{(1-y1)})_{1-y2}Ga_{y2}P; the AlInGaN series can be indicated as (Al_{z1}In_{(1-z1)})_{1-z2}Ga_{z2}N; the InGaAsP series can be indicated as In_{z3}Ga_{1-z3}As_{z4}P_{1-z4}; in which 0≤x1, y1, z1, x2, y2, z2, z3, z4≤1. The first active structure 100a2 and the second active structure 100b1 may include the same or different series of materials.

The base 114 can be a conductive substrate, including a conductive material such as gallium arsenide (GaAs), indium phosphide (InP), silicon carbide (SiC), gallium phosphide (GaP), zinc oxide (ZnO), gallium nitride (GaN), aluminum nitride (AlN), germanium (Ge) or silicon (Si).

The insulating layer 104 includes an electrically insulating material, such as oxide or fluoride. The oxide is, for example, silicon dioxide (SiOₓ), and the fluoride is, for example, magnesium fluoride (MgFₓ). In an embodiment, the insulating layer 104 includes an electrically insulating material, such as a low-refractive-index electrical insulating material with a refractive index lower than 1.4, such as magnesium fluoride (MgFₓ). The metal oxide layer 108 may be transparent and includes, but is not limited to, indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), zinc oxide (ZnO), gallium phosphide (GaP), indium cerium oxide (ICO), indium tungsten oxide (IWO), indium titanium oxide (ITiO), indium zinc oxide (IZO), indium gallium oxide (IGO), or gallium aluminum zinc oxide (GAZO). The reflective layer 110 is located on the bonding layer 112 and has a reflectivity of 80% or higher for the light emitted by the semiconductor epitaxial structure 100. The reflective layer 110 includes a conductive material, such as a metal or an alloy. The metal includes, for example, silver (Ag), gold (Au) or aluminum (Al). The bonding layer 112 may include a conductive material, such as a metal or an alloy. According to an embodiment, the melting point of the material used to form the bonding layer 112 is lower than 400° C., such that bonding of the base 114 and the reflective layer 110 can be done by soldering, eutectic bonding or thermocompression bonding.

The material of the first electrode 106 and the second electrode 116 may respectively include metal oxide, metal or alloy. The metal oxide includes indium tin oxide (ITO), indium oxide (InO), tin oxide (SnO), cadmium tin oxide (CTO), antimony tin oxide (ATO), aluminum zinc oxide (AZO), zinc oxide tin (ZTO), gallium zinc oxide (GZO), indium tungsten oxide (IWO), zinc oxide (ZnO) or indium zinc oxide (IZO). The metal includes germanium (Ge), beryllium (Be), zinc (Zn), gold (Au), platinum (Pt), titanium (Ti), aluminum (Al), nickel (Ni), or copper (Cu). The alloy, for example, includes two or more metals selected from the group consisting of the above metals, such as germanium-gold-nickel (GeAuNi), beryllium gold (BeAu), germanium gold (GeAu), or zinc gold (ZnAu).

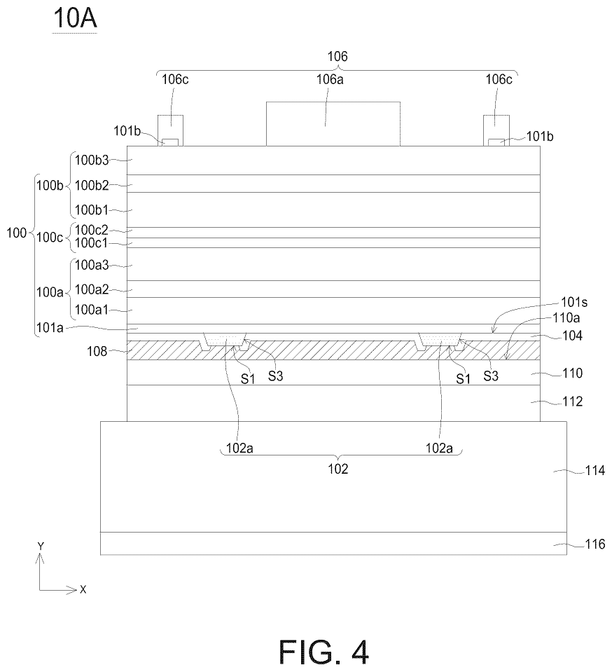

FIG. 4 shows a schematic cross-sectional view of a semiconductor device 10A according to an embodiment of the present disclosure. The difference between the semiconductor device 10A and the semiconductor device 10 mainly lies in the distribution of the metal contact structure 102, the insulating layer 104 and the metal oxide layer 108. In this embodiment, the metal oxide layer 108 overlaps with both the insulating layer 104 and the metal contact structure 102 in the vertical direction Y. The metal oxide layer 108 can be continuously distributed under the semiconductor epitaxial structure 100 and located among the reflective layer 110, the metal contact structure 102 and the insulating layer 104. A thickness of the metal oxide layer 108 may be greater than, less than or equal to the thickness of the metal pillar 102a. As shown in FIG. 4, a portion of the insulating layer 104 covers the first surface s1 where the metal pillar 102a is in contact with the metal oxide layer 108. In this embodiment, the electrical connection can be formed by directly contacting a portion of the metal pillar 102a which is not covered by the insulating layer 104 with the metal oxide layer 108. In an embodiment, the metal oxide layer 108 may be subjected to a grinding process, so that the metal oxide layer 108 can be flush with the insulating layer 104 as shown in FIG. 2. The reflective layer 110 is in direct contact with the metal oxide layer 108 and the insulating layer 104 and is not in direct contact with the metal pillar 102a.

The positions, relative relationships, and material compositions of other layers or structures well as structural variations in the semiconductor device 10A have been described in detail in previous embodiments, and are not repeatedly described herein.

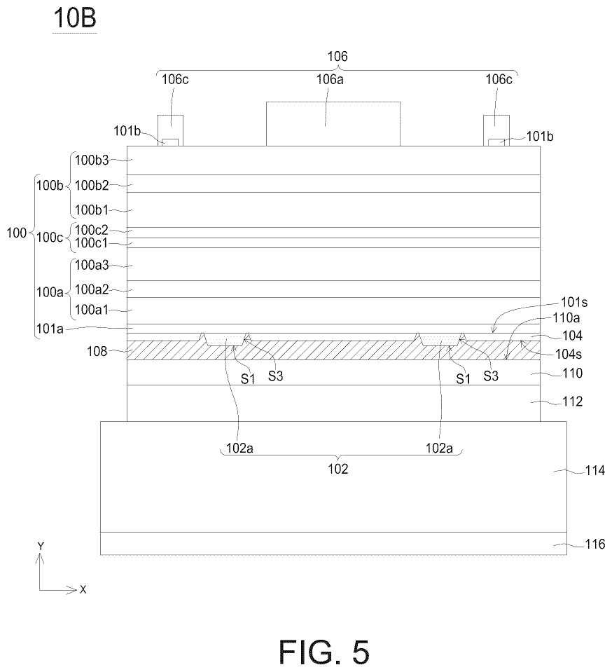

FIG. 5 shows a schematic cross-sectional view of a semiconductor device 10B according to an embodiment of the present disclosure. In the semiconductor device 10B, the metal contact structure 102 is not in direct contact with the insulating layer 104 and the metal contact structure 102 and the insulating layer 104 are separated by a distance. As shown in FIG. 5, the metal contact structure 102 and the insulating layer 104 are not overlapped in the vertical direction Y, but are overlapped in the horizontal direction X. In some embodiments, the thickness of the metal oxide layer 108 may be greater than, less than or equal to the thickness of the metal pillar 102a. In this embodiment, as shown in FIG. 5, a thickness of the metal pillar 102a may be greater than a thickness of the insulating layer 104. As shown in FIG. 5, the first surface s1 of the metal pillar 102a is not flush with a surface 104s of the insulating layer 104 which is connected to the metal oxide layer 108. In this embodiment, the metal oxide layer 108 directly contacts the first surface s1 and the side surface s3 of the metal pillar 102a, so that the metal pillar 102a can form an electrical connection with the metal oxide layer 108. In another embodiment, the metal oxide layer 108 in FIG. 5 is further subjected to a grinding process, so that a surface of the metal oxide layer 108 is flush with the first surface s1 of the metal pillar 102a. The reflective layer 110 is in direct contact with the metal oxide layer 108 and the metal pillars 102a but not in direct contact with the insulating layer 104.

In another embodiment, the thickness of the metal pillar 102a is equal to the thickness of the insulating layer 104, and the first surface s1 may be flush with the surface 104s. In this embodiment, the metal oxide layer 108 may be further subjected to a grinding process, so that the metal oxide layer 108 is flush with the insulating layer 104 and the metal pillar 102a. The reflective layer 110 is in direct contact with the metal oxide layer 108, the metal pillars 102a and the insulating layer 104 at the same time. The metal oxide layer 108 is located between the insulating layer 104 and the metal pillar 102a. The metal contact structure 102 (or the metal pillar 102a) is overlapped with the insulating layer 104 in the horizontal direction X and is not overlapped with the insulating layer in the vertical direction Y.

The positions, relative relationships, and material compositions of other layers or structures well as structural variations in the semiconductor device 10B have been described in detail in previous embodiments, and are not repeatedly described herein.

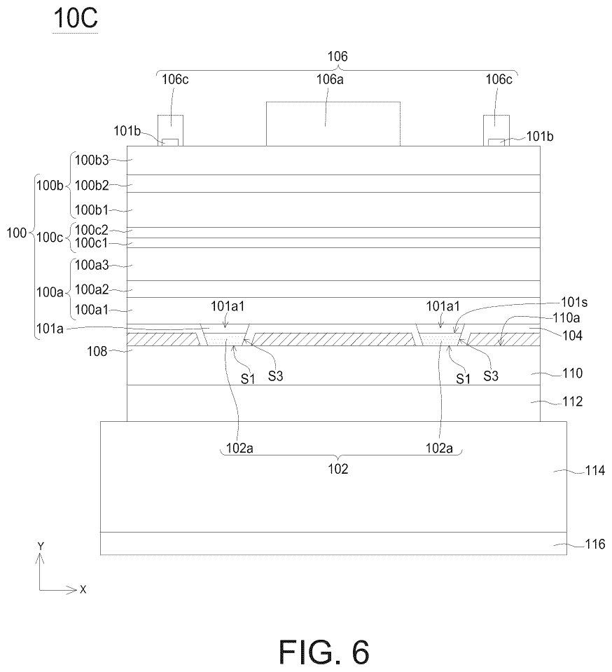

FIG. 6 shows a schematic cross-sectional view of a semiconductor device 10C according to an embodiment of the present disclosure. The semiconductor device 10C may have a patterned first semiconductor contact layer 101a. As shown in FIG. 6, the first semiconductor contact layer 101a may include a plurality of parts 101a1 that are separated with each other, and each of the plurality of parts 101a1 overlaps with the metal pillar 102a in the vertical direction Y and directly contacts the metal pillar 102a. In this embodiment, the insulating layer 104 covers a side surface of each of the plurality of parts 101a1 and the first surface s1 and the side surface s3 of the metal pillar 102a at the same time. The metal oxide layer 108 directly contacts the insulating layer 104 and does not directly contact the first semiconductor contact layer 101a and the metal contact structure 102. As shown in FIG. 6, from a cross-sectional view, each of the plurality of parts 101a1 of the first semiconductor contact layer 101a and/or the metal pillar 102a may be approximately in an inverted trapezoidal shape. The width of each of the plurality of parts 101a1 of the first semiconductor contact layer 101a and/or the width of the metal pillar 102a may gradually decrease from a side close to the first semiconductor structure 100a1 to a direction away from the first semiconductor structure 100a1. In this embodiment, through the patterned first semiconductor contact layer 101a and the metal contact structure 102, the semiconductor epitaxial structure 100 and the reflective layer 110 can be electrically connected. Since the first semiconductor contact layer 101a may absorb the light emitted by the semiconductor epitaxial structure 100, the patterned first semiconductor contact layer 101a can reduce light absorption and increase light extraction efficiency.

The positions, relative relationships, and material compositions of other layers or structures well as structural variations in the semiconductor device 10C have been described in detail in previous embodiments, and are not repeatedly described herein.

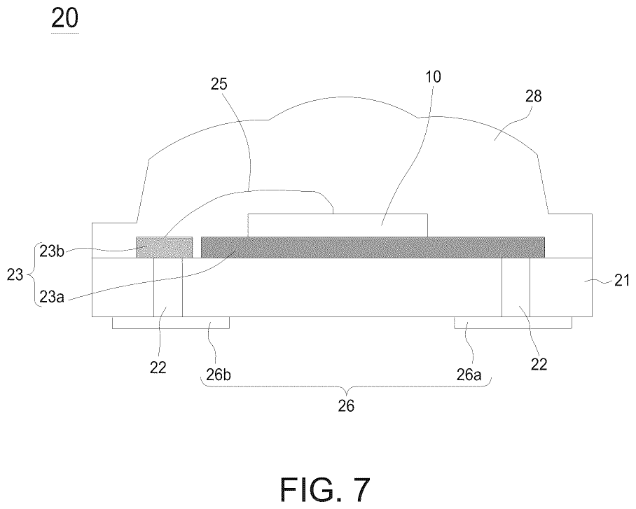

FIG. 7 shows a schematic cross-sectional view of a package structure 20 according to an embodiment of the present disclosure. As shown in FIG. 7, the package structure 20 includes a semiconductor device 10, a package substrate 21, a first conductive structure 23, a bonding wire 25, a second conductive structure 26 and an encapsulating material 28. The package substrate 21 may include ceramic or glass. The package substrate 21 has a plurality of through holes 22. Each through hole 22 may be filled with a conductive material such as metal for electrical conduction and/or heat dissipation. The first conductive structure 23 is located on a surface of one side of the package substrate 21 and may contain a conductive material such as metal. The second conductive structure 26 is located on a surface of another side of the package substrate 21. In this embodiment, the second conductive structure 26 includes a third contact pad 26a and a fourth contact pad 26b, and the third contact pad 26a and the fourth contact pad 26b can be electrically connected to the first conductive structure 23 through the through holes 22. In an embodiment, the second conductive structure 26 may further include a thermal pad (not shown), for example, located between the third contact pad 26a and the fourth contact pad 26b. The semiconductor device 10 is located on the first conductive structure 23 and may have a structure described in any embodiment or its variation in the present disclosure. In this embodiment, the first conductive structure 23 includes a first contact pad 23a and a second contact pad 23b, and the semiconductor device 10 is electrically connected to the second contact pad 23b of the first conductive structure 23 through a conductive wire 25. The material of the conductive wire 25 may include metal, such as gold (Au), silver (Ag), copper (Cu), or aluminum (Al), or may include alloy containing one or more of the above metals. The encapsulating material 28 covers the semiconductor device 10 to protect the semiconductor device 10. The encapsulation layer 28 may include a resin material, such as an epoxy resin, or a silicone resin. In an embodiment, the encapsulating material 28 may further include a plurality of wavelength conversion particles (not shown) to convert the light emitted by the semiconductor epitaxial structure 100.

Based on the above, the present disclosure can provide a semiconductor device and a package structure, and the structural design of which helps to improve optoelectronic characteristics of the semiconductor device. The semiconductor device or semiconductor package structure disclosed in this disclosure can be applied to products in various fields, such as illumination, medical care, display, communication, sensing, or power supply system, for example, can be used in a light fixture, monitor, mobile phone, tablet, an automotive instrument panel, a television, computer, wearable device (such as watch, bracelet or necklace), traffic sign, outdoor display, or medical device.

It should be realized that each of the embodiments mentioned in the present disclosure is used for describing the present disclosure, but not for limiting the scope of the present disclosure. Any obvious modification or alteration is not departing from the spirit and scope of the present disclosure. Furthermore, embodiments can be combined or substituted under proper condition and are not limited to specific embodiments described above. A connection relationship between a specific component and another component specifically described in an embodiment can also be applied in another embodiment and is within the scope as claimed in the present disclosure.

What is claimed is:

1. A semiconductor device, comprising:
a semiconductor epitaxial structure comprising an active structure and a semiconductor contact layer located on the active structure along a vertical direction;
a metal contact structure directly contacting the semiconductor contact layer; and
a metal oxide layer overlapped with the metal contact structure in a horizontal direction perpendicular to the vertical direction;
wherein the metal oxide layer and the metal contact structure are separated in the horizontal direction, the semiconductor epitaxial structure has a surface and the vertical direction is perpendicular to the surface.

2. The semiconductor device of claim 1, wherein the metal contact structure comprises a plurality of metal pillars separated with each other, one of the plurality of metal pillars comprises a first surface, a second surface and a side surface, in which the first surface directly contacts the semiconductor contact layer, the second surface is opposite to the first surface, and the side surface connects the first surface and the second surface.

3. The semiconductor device of claim 2, wherein the first surface and the side surface form an acute angle in a sectional view of the semiconductor device.

4. The semiconductor device of claim 2, wherein one of the plurality of metal pillars comprises a protrusion extended from the second surface.

5. The semiconductor device of claim 1, wherein in the vertical direction, the metal oxide layer has a first thickness, the metal contact structure has a second thickness, and the first thickness is less than the second thickness.

6. The semiconductor device of claim 1, further comprising an insulation layer directly contacts the semiconductor contact layer and the metal contact structure.

7. The semiconductor device of claim 6, wherein the insulation layer separates the metal oxide layer and the metal contact structure in the horizontal direction.

8. The semiconductor device of claim 6, wherein the insulation layer has a first refractive index, the semiconductor contact layer has a second refractive index, the metal oxide layer has a third refractive index, and the first refractive index is less than the second refractive index and the first refractive index is less than the third refractive index.

9. The semiconductor device of claim 6, further comprising a reflective layer directly contacts the metal oxide layer, the insulation layer and the metal contact structure.

10. The semiconductor device of claim 6, wherein the metal oxide layer is overlapped with the metal contact structure and the insulation layer in the vertical direction.

11. The semiconductor device of claim 6, wherein a portion of the insulation layer covers on the metal contact structure.

12. The semiconductor device of claim 11, wherein a portion of the metal contact structure not covered by the insulation layer directly contacts the metal oxide layer.

13. The semiconductor device of claim 1, further comprising a first electrode located on the semiconductor epitaxial structure, wherein the first electrode does not overlap with the metal contact structure in the vertical direction.

14. The semiconductor device of claim 1, wherein the metal contact structure comprises a main contact layer and a barrier layer connecting the main contact layer.

15. The semiconductor device of claim 14, wherein the barrier layer comprises Ta, Ti, Pt or TiW.

16. The semiconductor device of claim 1, wherein the metal contact structure directly contacts the metal oxide layer in the vertical direction.

17. The semiconductor device of claim 1, further comprising an insulation layer located between the semiconductor contact layer and the metal oxide layer.

18. The semiconductor device of claim 17, wherein the semiconductor contact layer comprises a plurality of parts separated from each other.

19. The semiconductor device of claim 18, wherein each of the plurality of parts is overlapped with the metal contact structure and directly contacts the metal contact structure in the vertical direction.

20. The semiconductor device of claim 19, wherein the metal oxide layer directly contacts the insulation layer.
